(19) United States
(12) Patent Application Publication
(10) Pub. No.: US 2025/0191943 A1
(43) Pub. Date: Jun. 12, 2025

(54) SUBSTRATE PROCESSING APPARATUS AND SUBSTRATE PROCESSING METHOD

(71) Applicant: SCREEN Holdings Co., Ltd., Kyoto (JP)

(72) Inventor: Shinji SHIMIZU, Kyoto (JP)

(21) Appl. No.: 18/844,346

(22) PCT Filed: Feb. 22, 2023
(86) PCT No.: PCT/JP2023/006359

§ 371 Date: Sep. 5, 2024

(30) Foreign Application Priority Data
Mar. 14, 2022 (JP) 2022-039158

(51) Int. Cl. H01L 21/67; H04N 23/21

(52) U.S. Cl. CPC H01L 21/67253; H01L 21/67051; H04N 23/21

(57) ABSTRACT

A substrate processing apparatus includes a chamber, a substrate holding section that rotates a substrate while holding the substrate in the chamber, a processing liquid supply section that supplies a processing liquid onto an upper surface of the substrate, a near-infrared light source that illuminates an inside of the chamber with near-infrared light, a near-infrared imaging section that generates a captured image by capturing an image of the processing liquid in the chamber illuminated with the near-infrared light from the near-infrared light source, and a controller. The controller specifies an outer edge of the processing liquid in the chamber based on the captured image.

### TECHNICAL FIELD

The present invention relates to a substrate processing apparatus and a substrate processing method.

### BACKGROUND ART

There are known substrate processing apparatuses for processing substrates. Substrate processing apparatuses are suitable for processing semiconductor substrates. Typically, substrate processing apparatuses process substrates using a processing liquid.

A substrate drying method is proposed for preventing particles from remaining on the periphery of a substrate in cleaning and drying the substrate (Patent Literature 1). The method described in Patent Literature 1 includes: measuring interference fringes generated from a thin film of a rinse liquid using a CCD camera when drying the rinse liquid on a substrate; and measuring the thickness of the rinse liquid from changes in the interference fringes.

### CITATION LIST

### Patent Literature

Patent Literature 1
JP 2004-335542 A

### SUMMARY OF INVENTION

### Technical Problem

General CCD cameras cannot detect a processing liquid on a substrate because the processing liquid used for substrate processing is transparent in general. For this reason, the substrate drying method of Patent Literature 1 uses a CCD camera to measure stripe-shaped interference fringes. The substrate drying method of Patent Literature 1 may however not be able to specify the processing liquid in a chamber with high accuracy.

The present invention has been achieved in view of the above circumstances, and an object thereof is to provide a substrate processing apparatus and a substrate processing method capable of specifying a processing liquid in a chamber with high accuracy.

### Solution to Problem

A substrate processing apparatus according to an aspect of the present invention includes a chamber, a substrate holding section, a processing liquid supply section, a near-infrared light source, a near-infrared imaging section, and a controller. The substrate holding section rotates a substrate while holding the substrate in the chamber. The processing liquid supply section supplies a processing liquid onto an upper surface of the substrate. The near-infrared light source illuminates an inside of the chamber with near-infrared light. The near-infrared imaging section generates a captured image by capturing an image of the processing liquid in the chamber illuminated with the near-infrared light from the near-infrared light source. The controller specifies an outer edge of the processing liquid in the chamber based on the captured image.

In an embodiment, the controller specifies a type of the processing liquid based on the captured image.

In an embodiment, the near-infrared imaging section captures the image of the processing liquid. The processing liquid is supplied onto the upper surface of the substrate from the processing liquid supply section.

In an embodiment, the controller determines whether or not the processing liquid has covered an entirety of the upper surface of the substrate based on the captured image.

In an embodiment, the processing liquid supply section includes a first processing liquid supply section and a second processing liquid supply section. The first processing liquid supply section supplies a first processing liquid to the substrate. The second processing liquid supply section supplies a second processing liquid to the substrate. The controller determines whether or not the second processing liquid has covered an entirety of the upper surface of the substrate based on the captured image after a supply start of the second processing liquid from the second processing liquid supply section to the substrate following a supply stop of the first processing liquid from the first processing liquid supply section to the substrate.

In an embodiment, the near-infrared light source and the near-infrared imaging section are placed outside the chamber.

In an embodiment, the near-infrared light source and the near-infrared imaging section are placed opposite to each other across the chamber.

In an embodiment, the near-infrared light source and the near-infrared imaging section are placed inside the chamber.

In an embodiment, the processing liquid supply section includes a pipe and a nozzle. The near-infrared imaging section captures the image of the processing liquid. The processing liquid is located at at least one of the pipe and the nozzle.

A substrate processing method according to another aspect of the present invention includes: rotating a substrate while holding the substrate in a chamber; supplying a processing liquid onto an upper surface of the substrate in the chamber; illuminating an inside of the chamber with near-infrared light; generating a captured image by capturing an image of the processing liquid in the chamber illuminated with the near-infrared light; and specifying an outer edge of the processing liquid in the chamber based on the captured image.

In an embodiment, the substrate processing method further includes specifying a type of the processing liquid based on the captured image.

In an embodiment, in the generating, the image of the processing liquid is captured in a state in which the upper surface of the substrate is supplied with the processing liquid.

In an embodiment, the substrate processing method further includes determining whether or not the processing liquid has covered an entirety of the upper surface of the substrate.

In an embodiment, the supplying includes: supplying a first processing liquid to the substrate; and supplying a second processing liquid to the substrate. The substrate processing method further includes determining whether or not the second processing liquid has covered an entirety of the upper surface of the substrate based on the captured image after a supply start of the second processing liquid to the substrate following a supply stop of the first processing liquid to the substrate.

In an embodiment, in generating, the image of the processing liquid is captured, the processing liquid being located at at least one of a pipe and a nozzle that allow the processing liquid to flow through.

### Advantageous Effects of Invention

Approach of the present invention enables high-precision specification of a processing liquid in the chamber.

### BRIEF DESCRIPTION OF DRAWINGS

FIG. 1 is a schematic diagram of a substrate processing apparatus according to the present embodiment.

FIG. 2 is a schematic diagram of a substrate processing unit in the substrate processing apparatus according to the present embodiment.

FIG. 3 is a block diagram of the substrate processing apparatus according to the present embodiment.

FIG. 4 is a flow chart of a substrate processing method according to the present embodiment.

FIG. 5 is a flow chart of a substrate processing process in the substrate processing method according to the present embodiment.

FIG. 6A is a schematic diagram of a captured image obtained by capturing an image of a substrate supplied with a processing liquid in a visible region in the substrate processing apparatus according to the present embodiment. FIG. 6B is a schematic diagram of a captured image of the substrate supplied with a processing liquid in the near-infrared region in the substrate processing apparatus according to the present embodiment.

FIG. 6C is a schematic diagram of a captured image obtained by capturing an image of the substrate supplied with another processing liquid in the near-infrared region in the substrate processing apparatus according to the present embodiment.

FIG. 7A is a schematic diagram of a captured image obtained by capturing an image of a substrate in the near-infrared region immediately after a start supply of a processing liquid in the substrate processing apparatus according to the present embodiment. FIG. 7B is a schematic diagram of a captured image obtained by capturing an image of the substrate with the processing liquid spreading on an upper surface thereof in the near-infrared region in the substrate processing apparatus according to the present embodiment. FIG. 7C is a schematic diagram of a captured image obtained by capturing an image of the substrate with the entirety of the upper surface covered with the processing liquid in the near-infrared region in the substrate processing apparatus according to the present embodiment.

FIG. 8 is a flow chart of a substrate processing process in a substrate processing method according to the present embodiment.

FIG. 9 is a flow chart of a substrate processing process in a substrate processing method according to the present embodiment.

FIG. 10 is a schematic diagram of a substrate processing unit in a substrate processing apparatus according to the present embodiment.

FIG. 11 is a schematic diagram of a substrate processing unit in a substrate processing apparatus according to the present embodiment.

FIG. 12A is a schematic diagram of a captured image obtained by capturing an image of a substrate supplied with a first processing liquid in a substrate processing apparatus according to the present embodiment. FIG. 12B is a schematic diagram of a captured image obtained by capturing an image of the substrate with the first processing liquid supply stopped and the supply of a second processing liquid started in the substrate processing apparatus according to the present embodiment. FIG. 12C is a schematic diagram of a captured imaging obtained by capturing an image of the substrate supplied with the second processing liquid in the substrate processing apparatus according to the present embodiment.

FIG. 13 is a flow chart of a substrate processing process in a substrate processing method according to the present embodiment.

FIG. 14 is a flow chart of a substrate processing process in a substrate processing method according to the present embodiment.

### DESCRIPTION OF EMBODIMENTS

Embodiments of a substrate processing apparatus and a substrate processing method of the present invention are described below with reference to the accompanying drawings. Note that elements which are the same or equivalent are labeled with the same reference signs in the drawings and description thereof is not repeated. To facilitate understanding of the invention, mutually orthogonal X-, Y-, and Z-axes may be described in the present description. Typically, X- and Y-axes are parallel to a horizontal direction, and a Z-axis is parallel to a vertical direction.

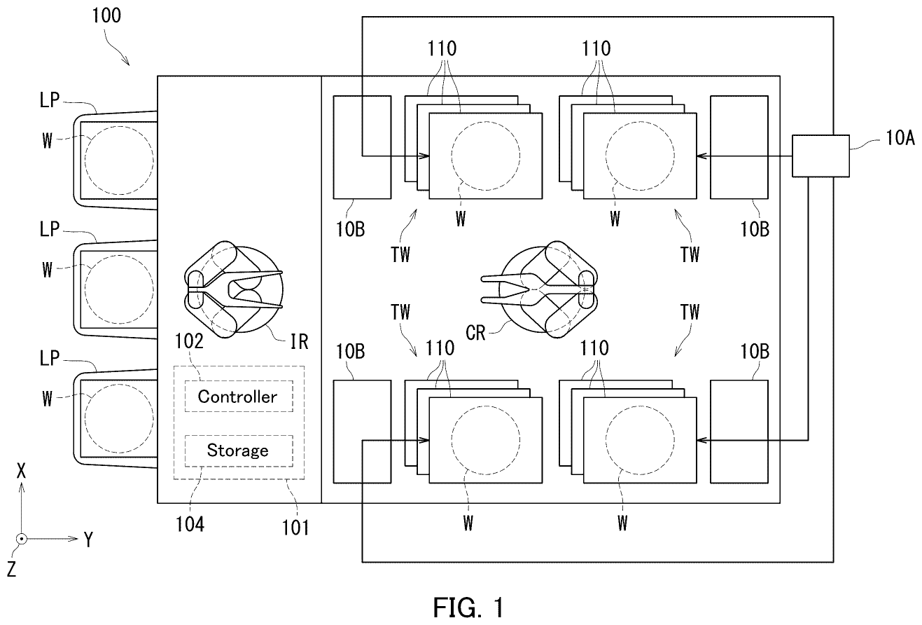

A substrate processing apparatus 100 according to the present embodiment is described with reference to FIG. 1. FIG. 1 is a schematic plan view of the substrate processing apparatus 100.

As depicted in FIG. 1, the substrate processing apparatus 100 processes substrates W. The substrate processing apparatus 100 processes substrates W such that at least one of the following is performed thereon: etching, surface finishing, characteristic imparting, process film forming, partial or complete removal of a film, and cleaning.

Substrates W are used as semiconductor substrates. Example of the substrates W include semiconductor wafers. For example, the substrates W are shaped like a disc. Here, the substrate processing apparatus 100 processes substrates W one at a time.

As depicted in FIG. 1, the substrate processing apparatus 100 includes substrate processing units 100, a fluid cabinet 10A, fluid boxes 10B, load ports LP, an indexer robot IR, a center robot CR, and a control device 101. The control device 101 controls the load ports LP, the indexer robot IR, the center robot CR, and the substrate processing units 110.

Each of the load ports LP accommodates and arranges multiple substrates W in a pile. The indexer robot IR conveys a substrate W between a load port LP and the center robot CR. Note that a device configuration may be used to indirectly transfer a substrate W between the indexer robot IR and the center robot CR via an installation table. Here, the installation table is provided between the indexer robot IR and the center robot CR to allow a substrate W to be temporarily placed on. The center robot CR conveys the substrate W between the indexer robot IR and one of the substrate processing units 110. The substrate processing unit 110 discharges a processing liquid to the substrate W to process the substrate W. The fluid cabinet 10A accommodates the processing liquid. Note that the fluid cabinet 10A may hold gas.

The substrate processing units 110 form towers TW (four towers TW in FIG. 1) arranged to surround the center robot CR in a plan view. Each tower includes substrate processing units 110 stacked vertically, that is, three substrate processing units 110 in FIG. 1. The fluid boxes 10B individually correspond to the towers TW. The processing liquid inside the fluid cabinet 10A is supplied, via any one of the fluid boxes 10B, to all substrate processing units 110 included in a tower TW corresponding to the fluid box 10B therebetween. Similarly, gas inside the fluid cabinet 10A is supplied, via any one of the fluid boxes 10B, to all substrate processing units 110 included in a tower TW corresponding to the fluid box 10B therebetween.

The control device 101 controls various operations of the substrate processing apparatus 100. The control device 101 includes a controller 102 and storage 104. The controller 102 includes a processor. The controller 102 includes, for example a central processing unit (CPU). Alternatively, the controller 102 may include a general-purpose arithmetic device.

The storage 104 includes main memory and auxiliary storage. Examples of the main memory include semiconductor memory. Examples of the auxiliary storage include semiconductor memory and/or a hard disk drive. The storage 104 may include a removable medium. The controller 102 executes a computer program stored in the storage 104 to perform substrate processing operations.

The storage 104 stores data therein. The data contains recipe data. The recipe data contains information on recipes. Each of the recipes defines the content and procedure for processing substrates W.

The storage 104 may store luminance value(s) of a reference processing liquid therein. Alternatively or additionally, the storage 104 may store a reference image obtained by capturing an image of the reference processing liquid.

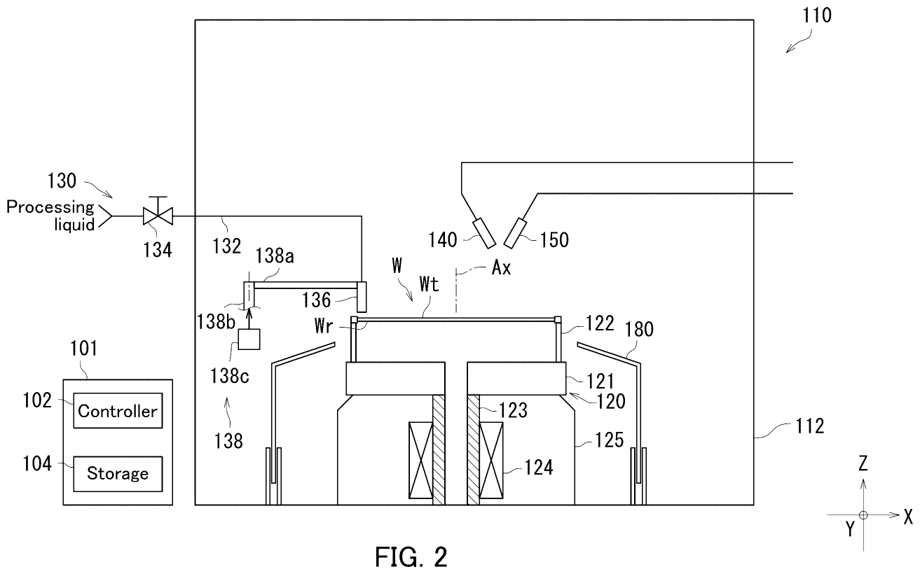

A substrate processing unit 110 in the substrate processing apparatus 100 according to the present embodiment is described next with reference to FIG. 2. FIG. 2 is a schematic diagram of the substrate processing unit 110 in the substrate processing apparatus 100.

The substrate processing unit 110 includes a chamber 112, a substrate holding section 120, a processing liquid supply section 130, a near-infrared light source 140, and a near-infrared imaging section 150. At least part of each of the following is accommodated in the chamber 112: the substrate holding section 120, the processing liquid supply section 130, the near-infrared light source 140, and the near-infrared imaging section 150.

The chamber 112 is shaped like a box with an internal space. The chamber 112 accommodates a substrate W. Here, the substrate processing unit 110 is a single-wafer type that processes substrates W one at a time. The chamber 112 accommodates one substrate W at a time. The substrate W is accommodated and processed in the chamber 112.

The substrate holding section 120 holds the substrate W. The substrate holding section 120 holds the substrate W horizontally with an upper surface (front surface) Wt of the substrate W up so that a lower surface (back surface) Wr of the substrate W faces vertically downward. The substrate holding section 120 also rotates the substrate W while holding the substrate W. The upper surface Wt of the substrate W may be flattened. Alternatively, the upper surface Wt of the substrate W may be provided with a device surface or a pillar-like laminate with a recess. The substrate holding section 120 rotates a substrate W while holding the substrate W.

For example, the substrate holding section 120 may be a clamping type that clamps the edge of the substrate W. Alternatively, the substrate holding section 120 may have any mechanism to hold the substrate W from the lower surface Wr. For example, the substrate holding section 120 may be a vacuum type. In this case, the substrate holding section 120 creates suction between an upper surface thereof and the center of the lower surface Wr of the substrate W, thereby holding the substrate W horizontally. Here, the lower surface Wr is a non-device forming surface. Alternatively, the substrate holding section 120 may be a combination of a clamping type and a vacuum type in which a plurality of chuck pins are brought into contact with the peripheral end surface of the substrate W.

For example, the substrate holding section 120 includes a spin base 121, a chuck member 122, a shaft 123, an electric motor 124, and a housing 125. The spin base 121 is provided with the chuck member 122. The chuck member 122 holds the substrate W with a chuck. Typically, the spin base 121 is provided with a plurality of chuck members 122.

The shaft 123 is a hollow shaft. The shaft 123 has a rotation axis Ax and extends vertically along the rotation axis Ax. The spin base 121 is coupled to the upper end of the shaft 123. A substrate W is placed above the spin base 121.

The spin base 121 is shaped like a disc. The chuck member 122 supports the substrate W horizontally. The shaft 123 extends downward from the center of the spin base 121. The electric motor 124 provides rotational force to the shaft 123. The electric motor 124 rotates the shaft 123 in a rotational direction, thereby rotating the substrate W and the spin base 121 around the rotation axis Ax. The housing 125 surrounds the shaft 123 and the electric motor 124.

The processing liquid supply section 130 supplies a processing liquid to a substrate W. Typically, the processing liquid supply section 130 supplies the processing liquid onto the upper surface Wt of the substrate W held by the substrate holding section 120. Note that the processing liquid supply section 130 may supply multiple types of processing liquids to the substrate W.

The processing liquid may be an etchant that etches substrates W. Examples of the etchant include hydrofluoric/nitric acid (a mixture of hydrofluoric acid (HF) and nitric acid (HNO₃)), hydrofluoric acid, buffered hydrogen fluoride (BHF), ammonium fluoride, a mixture of hydrofluoric acid and ethylene glycol (HFEG), and phosphoric acid (H₃PO₄). The type of etchant is not limited. For example, the etchant may be acidic or alkaline.

Alternatively, the processing liquid may be a rinse liquid. Examples of the rinse liquid include deionized water (DIW), carbonated water, electrolytic ionized water, ozone water, ammonia water, hydrochloric acid water at dilute concentrations (e.g., 10 ppm to 100 ppm), and reinjected water (hydrogen water).

Alternatively, the processing liquid may be an organic solvent. Typically, the volatility of organic solvents is higher than that of rinse liquids. Examples of the organic solvents include isopropyl alcohol (IPA), methanol, ethanol, acetone, hydrofluoroether (HFE), propylene glycol monoethyl ether (PGEE), and propylene glycol monomethyl ether acetate (PGMEA).

The processing liquid supply section 130 includes a pipe 132, a valve 134, a nozzle 136, and a moving mechanism 138. The pipe 132 allows the processing liquid from a supply source to flow through. The valve 134 opens and closes the flow path in the pipe 132. The nozzle 136 is connected to the pipe 132. The processing liquid flows through the nozzle 136. The nozzle 136 discharges the processing liquid onto the upper surface Wt of the substrate W. Preferably, the nozzle 136 is configured to be movable relative to the substrate W.

The pipe 132 and the nozzle 136 are made of resin. In this case, the near-infrared light emitted from the near-infrared light source 140 can pass through the pipe 132 and the nozzle 136.

The moving mechanism 138 moves the nozzle 136 horizontally and vertically. Specifically, the moving mechanism 138 has a rotation axis extending vertically and moves the nozzle 136 in a circumferential direction around the rotation axis. The moving mechanism 138 also raises and lowers the nozzle 136 in the vertical direction.

The moving mechanism 138 includes an arm 138a, a shaft 138b, and a driver 138c. The arm 138a extends horizontally. The nozzle 136 is placed on the tip of the arm 138a. The nozzle 136 is positioned at the tip of the arm 138a in an attitude that allows a processing liquid to be supplied toward the upper surface Wt of the substrate W held by the chuck member 122. Specifically, the nozzle 136 is coupled to the tip of the arm 138a and protrudes downward from the arm 138a. The proximal end of the arm 138a is coupled to the shaft 138b. The shaft 138b extends vertically.

The driver 138c includes a rotation drive mechanism and an elevation drive mechanism. The rotation drive mechanism of the driver 138c has a rotation axis and rotates the shaft 138b around the rotation axis and swivels the arm 138a around the shaft 138b in a horizontal plane. As a result, the nozzle 136 moves in the horizontal plane. Specifically, the nozzle 136 moves in a circumferential direction around the shaft 138b. Examples of the rotation drive mechanism of the driver 138c include a motor rotatable in forward and reverse directions.

The elevation drive mechanism of the driver 138c raises and lowers the shaft 138b in a vertical direction. The elevation drive mechanism of the driver 138c raises and lowers the shaft 138b, thereby raising and lowering the nozzle 136 vertically. The elevation drive mechanism of the driver 138c includes a drive source such as a motor and a lifting mechanism and drives the lifting mechanism by the drive source to raise or lower the shaft 138b. The lifting mechanism includes, for example, a rack and pinion mechanism or a ball screw.

The near-infrared light source 140 emits at least near-infrared light. The near-infrared light source 140 illuminates an inside of the chamber 112 with the near-infrared light. Specifically, the near-infrared light source 140 illuminates at least part of the inside of the chamber 112. Here, the near-infrared light source 140 emits the near-infrared light toward the substrate W.

For example, the near-infrared light source 140 emits near-infrared light whose wavelengths are included at least in a range of 800 nm or more and 2.5 μm or less. Typically, the near-infrared light source 140 emits near-infrared light whose wavelengths are included in a range of at least 800 nm or more and 1.5 μm or less.

Note that the near-infrared light source 140 may emit visible light along with near-infrared light. Alternatively, the near-infrared light source 140 may switch between near-infrared and visible light to be emitted. For example, the near-infrared light source 140 emits visible light. In this case, it is preferable to emit red light as visible light. This approach enables easy specification of the substrate W and the like in the chamber 112.

The near-infrared light source 140 has an optical axis and emits, for example near-infrared light travelling linearly along the optical axis. Alternatively, the near-infrared light source 140 emits near-infrared light travelling in a spreading manner around the optical axis. The near-infrared light source 140 is preferably placed with the optical axis of the near-infrared light source 140 passing through the center of a substrate W.

The near-infrared imaging section 150 includes pixels. The near-infrared imaging section 150 has sensitivity to at least near-infrared light. The near-infrared imaging section 150 generates a captured image by capturing an image of the inside of the chamber 112, by receiving components of near-infrared light emitted from the near-infrared light source 140 which have transmitted and/or have been reflected off members inside the chamber 112. Here, the near-infrared imaging section 150 receives components of near-infrared light emitted from the near-infrared light source 140 which have been reflected off the substrate W.

The near-infrared imaging section 150 captures an image of the inside of the chamber 112. The near-infrared imaging section 150 may capture an image of the entirety of the inside of the chamber 112. Alternatively, the near-infrared imaging section 150 may capture an image of a partial region of the inside of the chamber 112. In this case, the near-infrared imaging section 150 may capture images while switching between captured regions to be image-captured inside the chamber 112. Alternatively, the near-infrared imaging section 150 may capture images while switching between captured regions of the entirety and part of the inside of the chamber 112.

A frame rate of the near-infrared imaging section 150 may be 30 fps or 60 fps. Alternatively, the frame rate may be 120 fps.

The near-infrared imaging section 150 may include a short wavelength infra-red (SWIR) image sensor. In this case, the near-infrared imaging section 150 detects near-infrared light with wavelengths at least in a range of 800 nm or more and 2.5 μm or less.

Note that the near-infrared imaging section 150 may have sensitivity to not only near-infrared light but also visible light. Alternatively, the near-infrared imaging section 150 may receive near-infrared light and visible light in a switchable manner.

The near-infrared imaging section 150 captures an image of the surroundings centered on an imaging optical axis. Typically, the imaging optical axis is located at the center of a captured image. For example, the center of a captured image by the near-infrared imaging section 150 is located at the center of the substrate W. In this case, the imaging optical axis of the near-infrared imaging section 150 is located at the center of the substrate W. Alternatively, the center of a captured image by the near-infrared imaging section 150 may be located at the pipe 132 and/or the nozzle 136.

The near-infrared imaging section 150 generates a captured image by capturing an image of a member inside the chamber 112. Here, a processing liquid is present on the member. Preferably, the captured image enables specification of the processing liquid from the processing liquid supply section 130. For example, it is desirable that the captured image enables specification of the outer edge of the processing liquid supplied from the processing liquid supply section 130 to the substrate W. Alternatively, it is desirable that the captured image enables specification of the outer edge of the processing liquid, inside the pipe 132 and/or the nozzle 136, to be supplied from the processing liquid supply section 130 to the substrate W.

In a plan view of the substrate processing unit 110, the optical axis of the near-infrared light source 140 and the imaging optical axis of the near-infrared imaging section 150 are located on a straight line passing through the center of the substrate W. As described above, the near-infrared light source 140 and the near-infrared imaging section 150 may be placed at positions projected onto a horizontal line passing through the center of the substrate W.

Alternatively, in a plan view of the substrate processing unit 110, the optical axis of the near-infrared light source 140 and an imaging center of the near-infrared imaging section 150 may be perpendicular to each other at the center of the substrate W. As described above, the near-infrared light source 140 and the near-infrared imaging section 150 may be placed at positions perpendicular to each other with respect to the center of the substrate W.

Here, the near-infrared light source 140 and the near-infrared imaging section 150 are placed inside the chamber 112. The near-infrared light source 140 and the near-infrared imaging section 150 may be arranged and fixed.

The near-infrared light source 140 and the near-infrared imaging section 150 may be movable relative to the substrate W. Preferably, the near-infrared light source 140 and the near-infrared imaging section 150 may be movable horizontally and/or vertically according to operation of a moving mechanism that is controlled by a controller 102, for example. Here, the near-infrared light source 140 and the near-infrared imaging section 150 move. In this case, the near-infrared light source 140 and the near-infrared imaging section 150 may be movable independently of each other. Alternatively, the near-infrared light source 140 and the near-infrared imaging section 150 may be movable as one unit.

The processing liquid may contain organic material. For example, bonds such as C—H, C—O, C—N, and C—F in organic material absorb light with specific wavelengths in near-infrared light. The amount of absorption of near-infrared light at a specific wavelength is proportional to the amount of a component with a specific binding group. The amount of the specific component present in the substrate W can therefore be measured based on the near-infrared light reflected off the substrate W.

The substrate processing apparatus 100 further includes a cup 180. The cup 180 collects processing liquid scattered from the substrate W. The cup 180 moves up and down. For example, the cup 180 keeps a vertically risen state up to the side of the substrate W over a period of time during which the processing liquid supply section 130 supplies a processing liquid to the substrate W. In this case, the cup 180 collects the processing liquid scattered from the substrate W due to the rotation of the substrate W. The cup 180 also moves vertically downward from the side of the substrate W when the period of time, during which the processing liquid supply section 130 supplies the processing liquid to the substrate W, ends.

As described above, a control device 101 includes a controller 102 and storage 104. The controller 102 controls the substrate holding section 120, the processing liquid supply section 130, the near-infrared light source 140, the near-infrared imaging section 150, and/or the cup 180. In an example, the controller 102 controls the electric motor 124, the valve 134, the moving mechanism 134, the near-infrared light source 140, the near-infrared imaging section 150, and/or the cup 180.

In the substrate processing apparatus 100 according to the present embodiment, the near-infrared imaging section 150 captures an image of the processing liquid in the chamber 112 illuminated with near-infrared light from the near-infrared light source 140. Typically, the processing liquid is transparent and transmits visible light. By contrast, processing liquids often exhibit relatively strong absorption in the near-infrared region. The outer edge of the processing liquid in the chamber 112 can therefore be specified from a captured image obtained by capturing an image of the processing liquid using the near-infrared imaging unit 150.

Processing liquids may have a high absorbance to near-infrared light. In this case, the preferable configuration of the near-infrared light source 140 is to emit visible light along with near-infrared light. This approach enables captured images to present the processing liquid in the chamber 112 at a relatively high luminance.

In addition, processing liquids often exhibit specific absorptions in the near-infrared region according to their types. The type of the processing liquid in the chamber 112 can therefore be specified from a captured image obtained by capturing an image of the processing liquid using the near-infrared imaging unit 150.

Alternatively, the near-infrared light source 140 may change wavelengths of near-infrared light to be emitted in view of the fact that wavelengths exhibiting strong absorption differ among processing liquids. This approach enables easy specification of respective outer edges and types of the processing liquids.

The substrate processing apparatus 100 according to the present embodiment is suitably used for manufacturing semiconductor elements provided with a semiconductor. Typically, in a semiconductor element, a conductive layer, and an insulating layer are laminated on a substrate. The substrate processing apparatus 100 is suitably used for cleaning and/or processing (e.g., etching and characteristic change) the conductive layer and/or the insulating layer during the manufacture of semiconductor elements.

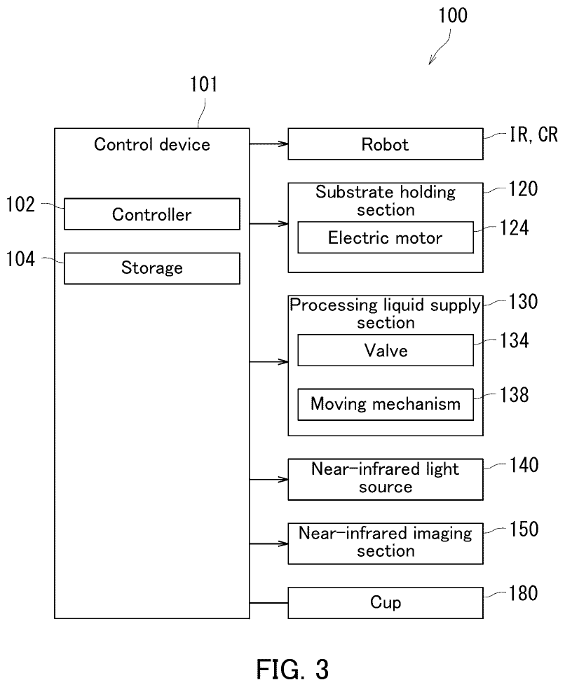

A substrate processing apparatus 100 according to the present embodiment will be described with reference to FIGS. 1 to 3. FIG. 3 is a block diagram of the substrate processing apparatus 100.

As depicted in FIG. 3, a control device 101 controls various operations of the substrate processing apparatus 100. The control device 101 controls an indexer robot IR, a center robot CR, a substrate holding section 120, a processing liquid supply section 130, a near-infrared light source 140, a near-infrared imaging section 150, and a cup 180. Specifically, the control device 100 transmits respective control signals to the indexer robot IR, the center robot CR, the substrate holding section 120, the processing liquid supply section 130, the near-infrared light source 140, the near-infrared imaging section 150, and the cup 180, thereby controlling the indexer robot IR, the center robot CR, the substrate holding section 120, the processing liquid supply section 130, the near-infrared light source 140, the near-infrared imaging section 150, and the cup 180

Storage 104 stores a computer program and data therein. The data contains recipe data. The recipe data contains information on a plurality of recipes. Each of the recipes defines processing contents, processing procedures, and substrate processing conditions for substrates W. A controller 102 executes the computer program stored in the storage 104 to cause substrate processing operations.

The controller 102 controls the indexer robot IR to transfer a substrate W through the indexer robot IR.

The controller 102 controls the center robot CR to transfer the substrate W through the center robot CR. For example, the center robot CR receives a substrate W to be processed and then loads the substrate W into one of the chambers 112. The center robot CR also receives a substrate W processed from the chamber 112 and then unloads the substrate W.

The controller 102 controls the substrate holding section 120 to start the rotation of the substrate W, change the rotation speed, and stop the rotation of the substrate W. For example, the controller 102 may change the rotation speed of the substrate holding section 120 by controlling the substrate holding section 120. Specifically, the controller 102 may change the rotation speed of the substrate W by changing the rotation speed of an electric motor 124 of the substrate holding section 120.

The controller 102 may control a valve 134 of the processing liquid supply section 130 to switch the state of the valve 134 between an open state and a closed state. Specifically, the controller 102 may control the valve 134 of the processing liquid supply section 130 to open the valve 134, thereby causing a processing liquid to flow in and pass through a pipe 132 toward a nozzle 136. The controller 102 may also control the valve 134 of the processing liquid supply section 130 to close the valve 134, thereby stopping the supply of the processing liquid flowing in the pipe 132 toward the nozzle 136.

The controller 102 may control a moving mechanism 138 of the processing liquid supply section 130 to move the nozzle 136. Specifically, the controller 102 may control the moving mechanism 138 of the processing liquid supply section 130 to move the nozzle 136 above the upper surface Wt of the substrate W. The controller 102 may also control the moving mechanism 138 of the processing liquid supply section 130 to move the nozzle 136 to a retracted position away from the position above the upper surface Wt of the substrate W.

The controller 102 controls the near-infrared light source 140 and the near-infrared imaging section 150 to capture an image of at least a partial region of the inside of the chamber 112, thereby generating a captured image. The controller 102 also controls the near-infrared light source 140 to illuminate at least a partial region of the inside of the chamber 112 with near-infrared light. The controller 102 also controls the near-infrared imaging section 150 to capture an image of at least a partial region of the inside of the chamber 112, thereby generating a captured image. The near-infrared imaging section 150 captures an image of the processing liquid supplied from the processing liquid supply section 130 and/or of a region, inside the processing liquid supply section 130, in which the processing liquid is present.

For example, the controller 102 controls the near-infrared light source 140 and the near-infrared imaging section 150 to emit near-infrared light toward the substrate W from the near-infrared light source 140 and then to receive the near-infrared light reflected off the substrate W through the near-infrared imaging section 150, thereby measuring luminance value(s). Note that the controller 102 may control the near-infrared light source 140 and the near-infrared imaging section 150 to move the near-infrared light source 140 and the near-infrared imaging section 150 relative to the substrate W.

The controller 102 specifies the outer edge of the processing liquid in the captured image. For example, the controller 102 specifies the outer edge of the processing liquid in the captured image based on the luminance value in the captured image. In an example, the controller 102 specifies the outer edge of the processing liquid in the captured image based on the luminance value in the captured image and a luminance value of a reference processing liquid stored in the storage 104. Alternatively, the controller 102 specifies the outer edge of the processing liquid in the captured image based on the captured image and a reference image.

The controller 102 also specifies the type of the processing liquid in the captured image based on luminance values in the captured image. The type of the processing liquid in the captured image is specified based on the luminance value in the captured image and the luminance values of the reference processing liquid stored in the storage 104. Alternatively, the controller 102 specifies the type of the processing liquid in the captured image based on the captured image and the reference image.

The controller 102 may control the cup 180 to move the cup 180 relative to the substrate W. Specifically, the controller 102 keeps a vertically risen state of the cup 180 up to the side of the substrate W over a period of time during which the processing liquid supply section 130 supplies the processing liquid to the substrate W. The controller 102 also moves the cup 180 vertically downward from the side of the substrate W when the period of time, during which the processing liquid supply section 130 supplies the processing liquid to the substrate W, ends.

The substrate processing apparatus 100 according to the present embodiment is suitably used for forming semiconductor elements. For example, the substrate processing apparatus 100 is suitably used to process substrates W used as a semiconductor element having a stacked structure. The semiconductor element is so-called 3D structured memory (storage device). As an example, the substrate W is suitably used as NAND flash memory.

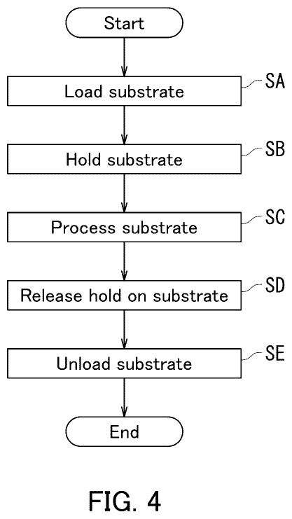

A substrate processing method according to the present embodiment is described next with reference to FIGS. 1 to 4. FIG. 4 is a flow chart of the substrate processing method.

As depicted in FIG. 4, in Step SA, substrates W are carried in a substrate processing apparatus 100. Specifically, a substrate W is loaded into a chamber 112 of a substrate processing unit 110 through an indexer robot IR and a center robot CR.

In Step SB, the substrate W is held. Specifically, a substrate holding section 120 holds the substrate W. The substrate W is loaded into the chamber 112 and then held by the substrate holding section 120.

In Step SC, the substrate W is processed. The substrate W is processed in the substrate processing unit 110. Typically, the substrate holding section 120 rotates the substrate W while holding the substrate W, and a processing liquid supply section 130 supplies a processing liquid to the substrate W.

In the present embodiment, a near-infrared light source 140 emits near-infrared light. At least part of the chamber 112 is illuminated with the near-infrared light emitted from the near-infrared light source 140. For example, the substrate W in the chamber 112 is illuminated with the near-infrared light emitted from the near-infrared light source 140. A near-infrared imaging section 150 captures an image of the chamber 112 illuminated with the near-infrared light. For example, the near-infrared imaging section 150 captures an image of the substrate W illuminated with infrared light. Capturing an image of the chamber 112 illuminated with the near-infrared light from the near-infrared imaging section 150 enables high-precision imaging of the processing liquid even if the processing liquid in the chamber 112 is substantially transparent.

In Step SD, hold on the substrate W is released. Specifically, the substrate holding section 120 releases hold on the substrate W.

In Step SE, the substrate W is unloaded. The substrate W is unloaded from the substrate processing apparatus 100. Specifically, the substrate W is unloaded from the chamber 112 of the substrate processing unit 110 through the center robot CR and the indexer robot IR.

In the present embodiment, an image of the processing liquid is captured by the near-infrared imaging section 150 with the processing liquid illuminated by the near-infrared from the near-infrared light source 140. Since the processing liquid absorbs the near-infrared light at a relatively high rate, the outer edge of the processing liquid can be specified with high precision.

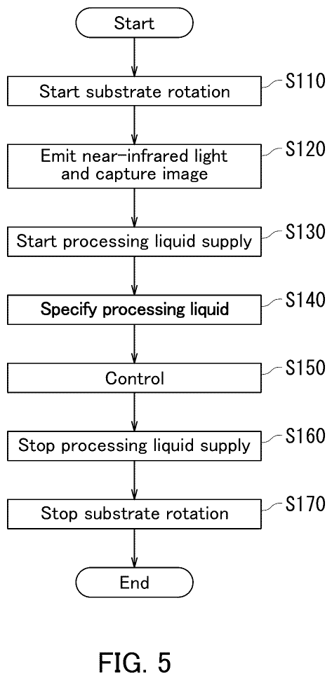

A substrate processing process in a substrate processing method according to the present embodiment is described with reference to FIGS. 1 to 5. FIG. 5 is a flow chart of the substrate processing process in the substrate processing method according to the present embodiment.

As depicted in FIG. 5, in Step S110, a substrate W is rotated in a held state. Specifically, a substrate holding section 120 rotates the substrate W while holding the substrate W. For example, the rotational speed of the substrate W is between 10 rpm and 1500 rpm.

In Step S120, a near-infrared light source 140 illuminates the substrate W with near-infrared light, while a near-infrared imaging section 150 captures an image of the substrate W illuminated with the near-infrared light. The near-infrared light source 140 illuminates the substrate W with near-infrared light, while the near-infrared imaging section 150 captures an image of the substrate W illuminated with the near-infrared light, thereby generating a captured image. A controller 102 controls the near-infrared light source 140 to cause the near-infrared light source 140 to emit near-infrared light toward the substrate W, and controls the near-infrared imaging section 150 to cause the near-infrared imaging section 150 to capture an image of the substrate W. Note that the timing at which the near-infrared light source 140 starts emitting near-infrared light may be the same as or different from the timing at which the near-infrared imaging section 150 starts capturing an image of the substrate W. The timing at which the near-infrared light source 140 starts emitting near-infrared light may be earlier or later than the timing at which the near-infrared imaging section 150 starts capturing an image of the substrate W.

In Step S130, a processing liquid is supplied to the substrate W. Specifically, the controller 102 controls a processing liquid supply section 130 to cause the processing liquid supply section 130 to start supplying the processing liquid to the substrate W.

Note that processing liquid supply in Step S130 may start before or after emission by the near-infrared and/or image capture by the near-infrared imaging section 150 in Step S120.

In Step S140, based on the captured image generated by the near-infrared imaging section 150, the processing liquid in the captured image is specified. The controller 102 specifies the processing liquid in the captured image based on the captured image. The controller 102 specifies, for example, the outer edge of the processing liquid in the captured image based on the captured image. The controller 102 may also specify the type of the processing liquid in the captured image based on the captured image.

For example, the controller 102 specifies the outer edge of the processing liquid in the captured image based on luminance value in the captured image. For example, the controller 102 specifies the outer edge of the processing liquid in the captured image based on the luminance value in the captured image and a luminance value of a reference processing liquid stored in storage 104. Alternatively, the controller 102 specifies the outer edge of the processing liquid in the captured image based on the captured image and a reference image.

The controller 102 also specifies the type of the processing liquid in the captured image based on the luminance values in the captured image. The type of the processing liquid in the captured image is specified based on the luminance values in the captured image and the luminance values of the reference processing liquid stored in the storage 104. Alternatively, the controller 102 specifies the type of the processing liquid in the captured image based on the captured image and the reference image.

In Step S150, a substrate processing unit 110 is controlled based on the results of specifying the processing liquid. Specifically, the controller 102 controls the substrate processing unit 110 based on the results of specifying the outer edge of the processing liquid.

For example, the controller 102 controls the processing liquid supply section 130 to change the processing liquid supply. In an example, the controller 102 controls the processing liquid supply section 130 to change the flow rate of the processing liquid. Alternatively, the controller 102 controls the processing liquid supply section 130 to change a processing liquid to be supplied to the substrate W.

In Step S160, the processing liquid supply is stopped. Specifically, the controller 102 controls the processing liquid supply section 130 to cause the processing liquid supply section 130 to stop supplying the processing liquid to the substrate W.

In Step S170, the rotation of the substrate W is stopped. Specifically, the controller 102 controls the substrate holding section 120 to cause the substrate holding section 120 to stop rotating the substrate W.

In the present embodiment, an image of the substrate W illuminated with the near-infrared light from the near-infrared light source 150 is captured. The near-infrared light is selectively absorbed into the processing liquid. It is therefore possible to capture an image of the processing liquid on the upper surface Wt of the substrate W with high precision. This approach enables the controller 102 to control processing of the substrate W according to the state of the processing liquid on the upper surface Wt of the substrate W.

As described above, the near-infrared light source 140 may switch between visible light and near-infrared light to be emitted. The near-infrared imaging section 150 may also capture images while switching between the visible light region and the near-infrared region.

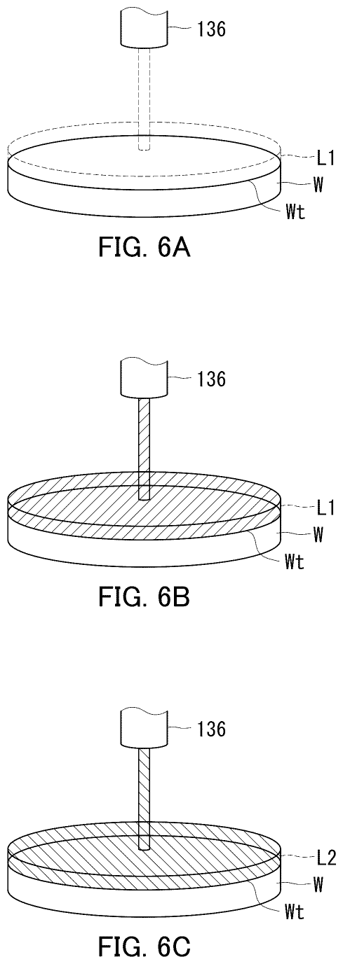

A substrate processing apparatus 100 is described next with reference to FIGS. 6A to 6C. FIG. 6A is a schematic diagram of a captured image obtained by capturing an image of a substrate W to be supplied with a processing liquid L1 in the visible region. FIG. 6B is a schematic diagram of a captured image of the substrate W supplied with the processing liquid L1 in the near-infrared region. FIG. 6C is a schematic diagram of a captured image obtained by capturing an image of the substrate W supplied with a processing liquid L2 in the near-infrared region.

As depicted in FIG. 6A, a nozzle 136 discharges the processing liquid L1 onto an upper surface Wt of the substrate W. Here, the nozzle 136 discharges the processing liquid L1 toward the center of the upper surface Wt of the substrate W. Since the substrate W is rotating, the processing liquid L1 spreads radially from the center of the upper surface Wt of the substrate W, so that the processing liquid L1 covers the entirety of the upper surface Wt of the substrate W. Note that processing liquid that has reached the radial edge of the upper surface Wt of the substrate W scatters radially outward from the substrate W.

The processing liquid L1 is transparent to visible light. The outer edge of the processing liquid L1 on the upper surface Wt of the substrate W cannot therefore be specified even if an image of the substrate W supplied with the processing liquid L1 is captured in the visible region.

Specifically, when a liquid film of the processing liquid L1 becomes thin and interference fringes occur in the processing liquid L1, the interference fringes that occur discretely in the processing liquid L1 can be specified from a captured image taken in the visible region. Alternatively, if there is unevenness in the thickness of the liquid film on the upper surface Wt of the processing liquid L1, the processing liquid L1 can be partially specified based on the unevenness in the thickness of the processing liquid L1 that occurs discretely in the processing liquid L1 from a captured image taken in the visible region. However, when an image of a substrate W supplied with the processing liquid L1 is captured in the visible region, the outer edge of the processing liquid L1 on the upper surface Wt of the substrate W cannot be specified in general.

In the case depicted in FIG. 6B, an image of the substrate W supplied with the processing liquid L1 is captured in the near-infrared region. In this case, the processing liquid L1 effectively absorbs near-infrared light. This enables the processing liquid L1 on the upper surface Wt of the substrate W to be specified with height precision from the captured image. Therefore, the outer edge of the processing liquid L1 can be specified.

In the case depicted in FIG. 6C, the nozzle 136 discharges the processing liquid L2 onto the upper surface Wt of the substrate W. In this case, an image of the substrate W is captured in the near-infrared region. The processing liquid L2 effectively absorbs near-infrared light in a different manner than the processing liquid L1. This enables the processing liquid L2 on the upper surface Wt of the substrate W to be specified with high precision.

In the present embodiment as described above, the near-infrared imaging section 150 captures respective images of the processing liquids L1 and L2 illuminated with the near-infrared light. The processing liquids L1 and L2 absorb near-infrared light at a relatively high rate, thereby enabling the outer edges of the processing liquids L1 and L2 to be specified with high precision. The processing liquids L1 and L2 absorb near-infrared light in different manners, thereby enabling the respective types of the processing liquids L1 and L2 to be specified with high precision.

Note that in the present embodiment, the outer edge of a processing liquid can be specified with high precision and therefore changes in the processing liquid on the upper surface Wt of the substrate W can be specified.

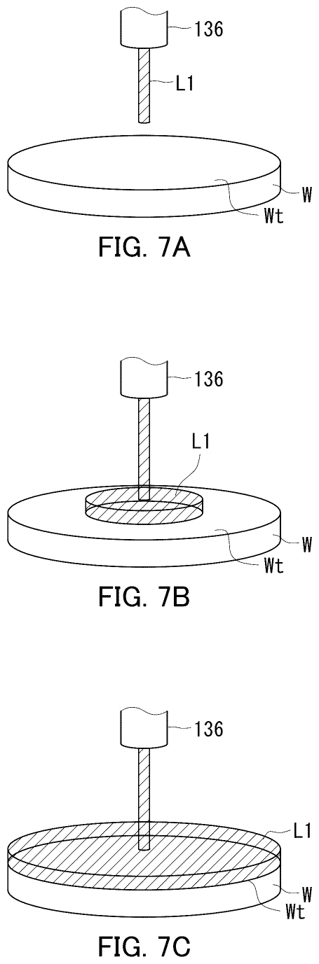

A substrate processing apparatus 100 according to the present embodiment is described next with reference to FIGS. 7A to 7C. FIG. 7A is a schematic diagram of a captured image obtained by capturing an image of a substrate W immediately after discharging a processing liquid L1 onto an upper surface Wt is started in a substrate processing apparatus 100 according to the present embodiment. FIG. 7B is a schematic diagram of a captured image obtained by capturing an image of the substrate W with the processing liquid L1 spreading on the upper surface Wt in the substrate processing apparatus 100 according to the present embodiment. FIG. 7C is a schematic diagram of a captured image obtained by capturing an image of the substrate W with the entirety of the upper surface Wt of the substrate W covered with the processing liquid L1 in the substrate processing apparatus 100 according to the present embodiment.

As depicted in FIG. 7A, a nozzle 136 starts discharging the processing liquid L1 onto the upper surface Wt of the substrate W. Specifically, the nozzle 136 starts discharging the processing liquid L1 toward the center of the upper surface Wt of the substrate W. Here, the substrate W is rotated at a predetermined rotational speed.

Here, the upper surface Wt of the substrate W is not covered with the processing liquid and is dry. Typically, near-infrared light is strongly reflected when the upper surface Wt of the substrate W is illuminated with near-infrared light emitted from a near-infrared light source 140 in a state in which the upper surface Wt of the substrate W is not covered with the processing liquid. Therefore, in a captured image in which the upper surface Wt of the substrate W that is not covered with the processing liquid L1 exhibits a high luminance value.

As depicted in FIG. 7B, as the nozzle 136 continues to discharge the processing liquid L1 onto the upper surface Wt of the substrate W, the processing liquid L1 spreads over the upper surface Wt of the substrate W. Specifically, as the nozzle 136 continues to discharge the processing liquid L1 toward the center of the upper surface Wt of the substrate W, the processing liquid L1 spreads radially from the center of the upper surface Wt of the substrate W.

As described above, of the upper surface Wt of the substrate W, a region that is not covered with the processing liquid L1 exhibits relatively high luminance values in the captured image in a state in which the upper surface Wt of the substrate W is not covered with the processing liquid L1. By contrast, in a region of the upper surface Wt of the substrate W that is covered with the processing liquid L1, near-infrared light is strongly absorbed into the processing liquid L1 when the upper surface Wt of the substrate W is illuminated with the near-infrared light emitted from the near-infrared light source 140. Therefore, in the captured image, the region covered with the processing liquid L1 of the upper surface Wt of the substrate W exhibits relatively low luminance values.

As depicted in FIG. 7C, as the nozzle 136 continues to discharge the processing liquid L1 onto the upper surface Wt of the substrate W, the processing liquid L1 spreads over the entirety of the upper surface Wt of the substrate W, so that the processing liquid L1 covers the entirety of the upper surface Wt of the substrate W. Specifically, as the nozzle 136 continues to discharge the processing liquid L1 toward the center of the upper surface Wt of the substrate W, the processing liquid L1 spreads radially from the center of the upper surface Wt of the substrate W, so that the processing liquid L1 covers the entirety of the upper surface Wt of the substrate W. Note that processing liquid L1 that has reached the radial edge of the upper surface Wt of the substrate W scatters radially outward from the substrate W.

When the upper surface Wt of the substrate W is illuminated with the near-infrared light emitted from the near-infrared light source 140 in a state in which the processing liquid L1 covers the entirety of the upper surface Wt of the substrate W, the near-infrared light is strongly absorbed into the processing liquid L1. Therefore, in the captured image, the region covered with the processing liquid L1 of the upper surface Wt of the substrate W exhibits relatively low luminance values.

In the present embodiment, the substrate W supplied with the processing liquid L1 is illuminated with near-infrared light from the near-infrared light source 140 and an image of the substrate W is captured by a near-infrared imaging section 150. Therefore, changes of the outer edge of the processing liquid L1 can be specified with high precision.

Although the captured images as described with reference to FIGS. 7A to 7C are obtained by capturing images of a process of the processing liquid L1 spreading radially from the center of the upper surface Wt of the substrate W from a discharge start of the processing liquid L1 from the nozzle 136, the present embodiment is not limited to this. The near-infrared imaging section 150 may capture images of a process of the processing liquid L1 disappearing from the upper surface Wt of the substrate W due to drying.

In the substrate processing method according to the present embodiment, the flow rate of a processing liquid to be supplied from a processing liquid supply section 130 onto the upper surface Wt of the substrate W may be changed based on the results of specifying the outer edge of the processing liquid.

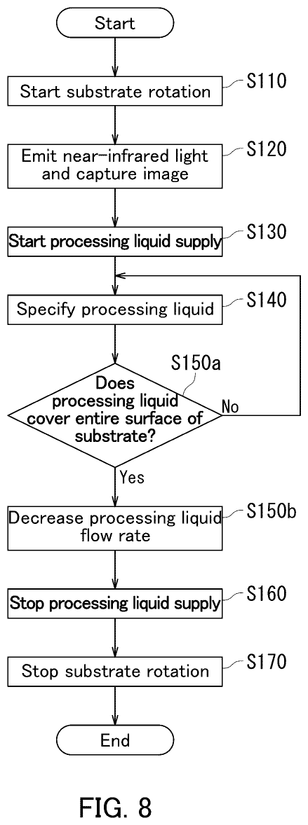

A substrate processing process in a substrate processing method according to the present embodiment is described next with reference to FIGS. 1 to 8. FIG. 8 is a flow chart of the substrate processing process in the substrate processing method according to the present embodiment. The flow chart of FIG. 8 is the same as the flow chart of FIG. 5 except that it is determined whether or not a processing liquid covers an upper surface Wt of a substrate W based on results of specifying the outer edge of the processing liquid and the flow rate of the processing liquid to be supplied from a processing liquid supply section 130 onto the upper surface Wt of the substrate W is changed. Duplicate descriptions are therefore omitted for the purpose of avoiding redundancy.

As depicted in FIG. 8, Steps S110 and S120 are the same as Steps S110 and S120 in FIG. 5, respectively.

In Step S130, the substrate W is supplied with the processing liquid. A controller 102 controls the processing liquid supply section 130 to cause the processing liquid supply section 130 to start supplying the processing liquid to the substrate W. Here, the processing liquid is supplied to the substrate W in a dry state. In this case, the flow rate of the processing liquid is set to a relatively large value.

In Step S140, the processing liquid in a captured image is specified based on the captured image generated by a near-infrared imaging section 150. The controller 102 specifies the outer edge of the processing liquid in the captured image based on the captured image. The controller 102 may also specify the type of the processing liquid in the captured image based on the captured image.

In Step S150a, whether or not the processing liquid has covered the entirety of an upper surface Wt of the substrate W is determined. Specifically, the controller 102 determines whether or not the processing liquid has covered the entirety of the upper surface Wt of the substrate W based on the results of specifying the outer edge of the processing liquid.

If the processing liquid has not covered the entirety of the upper surface Wt of the substrate W (No in Step S150a), the routine returns to Step S140. In the manner described above, specification of the outer edge of the processing liquid and determination as to entire surface covering are repeated until the entirety of the upper surface Wt of the substrate W is covered with the processing liquid. If the processing liquid has covered the entirety of the upper surface Wt of the substrate W (Yes in Step S150a) by contrast, the routine proceeds to Step S150b.

In Step S150b, the flow rate of the processing liquid to be supplied to the substrate W is decreased. The controller 102 controls the processing liquid supply section 130 to cause the processing liquid supply section 130 to decrease the flow rate of the processing liquid to be supplied to the substrate W.

For example, the controller 102 may decrease the flow rate of the processing liquid up to a preset flow rate. Alternatively, the controller 102 may decrease the flow rate of the processing liquid while specifying the outer edge of the processing liquid on the upper surface Wt of the substrate W. In this case, the processing liquid supply section 130 continues supplying the processing liquid for a predetermined period. Thereafter, the routine proceeds to Step S160. Note that Steps S160 and S170 are the same as Steps S160 and S170 in FIG. 5, respectively.

In the present embodiment, the flow rate of the processing liquid to be supplied from the processing liquid supply section 130 onto the upper surface Wt of the substrate W is decreased based on the results of specifying the outer edge of the processing liquid. Therefore, no extra amount of the processing liquid is necessary to ensure entire coverage of the upper surface Wt of the substrate W.

Although the processing liquid supply section 130 supplies a relatively large amount of the processing liquid previously to cover the entirety of the upper surface Wt of the substrate W with the processing liquid and then the flow rate of the processing liquid to be supplied from the processing liquid supply section 130 is decreased in the flow chart of FIG. 8, the present embodiment is not limited to this. The processing liquid supply section 130 may supply a relatively small amount of the processing liquid previously and then the flow rate of the processing liquid to be supplied from the processing liquid supply section 130 is increased if the entirety of the upper surface Wt of the substrate W is not yet covered within a predetermined period.

Although the flow rate of the processing liquid is changed based on the results of specifying the outer edge of the processing liquid in the description with reference to FIG. 8, the present embodiment is not limited to this. Processing liquid supply from the processing liquid supply section 130 onto the upper surface Wt of the substrate W may be stopped based on the results of specifying the outer edge of the processing liquid.

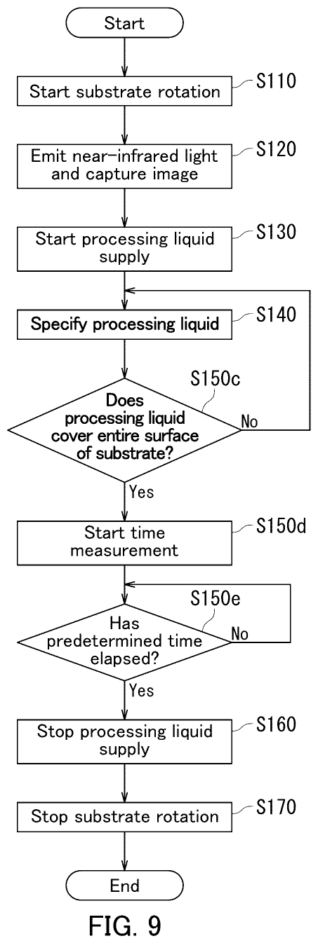

A substrate processing process in a substrate processing method according to the present embodiment is described next with reference to FIGS. 1 to 9. FIG. 9 is a flow chart of the substrate processing process in the substrate processing method according to the present embodiment. The flow chart of FIG. 9 is the same as the flow chart of FIG. 5 except that processing liquid supply is stopped based on results of specifying the outer edge of a processing liquid. Duplicate descriptions are therefore omitted for the purpose of avoiding redundancy.

As depicted in FIG. 9, Steps S110 and S120 are the same as Steps S110 and S120 in FIG. 5, respectively.

In Step S130, the processing liquid is supplied to a substrate W. A controller 102 controls a processing liquid supply section 130 to cause the processing liquid supply section 130 to start supplying the processing liquid to the substrate W. Here, the processing liquid is supplied to the substrate W in a dry state.

In Step S140, the processing liquid in a captured image generated by a near-infrared imaging section 150 is specified based on the captured image. The controller 102 specifies the outer edge of the processing liquid in the captured image based on the captured image. The controller 102 may also specify the type of the processing liquid in the captured image based on the captured image.

In Step S150c, whether or not the processing liquid has covered the entirety of the upper surface Wt of the substrate W is determined. Specifically, the controller 102 determines whether or not the processing liquid has covered the entirety of the upper surface Wt of the substrate W based on the results of specifying the outer edge of the processing liquid.

If the processing liquid has not covered the entirety of the upper surface Wt of the substrate W (No in Step S150c), the routine returns to Step S140. In the manner described above, specification of the outer edge of the processing liquid and determination as to entire surface covering are repeated until the processing liquid covers the entirety of the upper surface Wt of the substrate W. If the processing liquid has covered the entirety of the upper surface Wt of the substrate W (Yes in Step S150c) by contrast, the routine proceeds to Step S150d.

In Step S150d, time measurement is started. The controller 102 measures an elapsed time from when the processing liquid covers the entirety of the upper surface Wt of the substrate W, while continuing to control the processing liquid supply section 130 to continue to supply the processing liquid to the substrate W.

In Step S150e, whether or not a predetermined time has elapsed from a start of time measurement is determined. If the predetermined time has not yet elapsed (No in Step S150e), the routine returns to Step S150e. In the manner described above, determination is repeated from the start of time measurement to elapse of the predetermined time. If the predetermined time has elapsed (Yes in Step S150e) by contrast, the routine proceeds to Step S160. Note that Steps S160 and S170 are the same as Steps S160 and S170 in FIG. 5, respectively.

In the present embodiment, a time during which the processing liquid is supplied from the processing liquid supply section 130 onto the upper surface Wt of the substrate W is measured based on the results of specifying the outer edge of the processing liquid. Thus, variations in processing among substrates W can be suppressed even if variations occur during a process until a processing liquid covers an upper surface Wt of a substrate W.

Although the near-infrared light source 140 and the near-infrared imaging section 150 are placed in the chamber 112 in the above description with reference to FIGS. 1 to 9, the present embodiment is not limited to this. The near-infrared light source 140 and the near-infrared imaging section 150 may be placed outside the chamber 112.

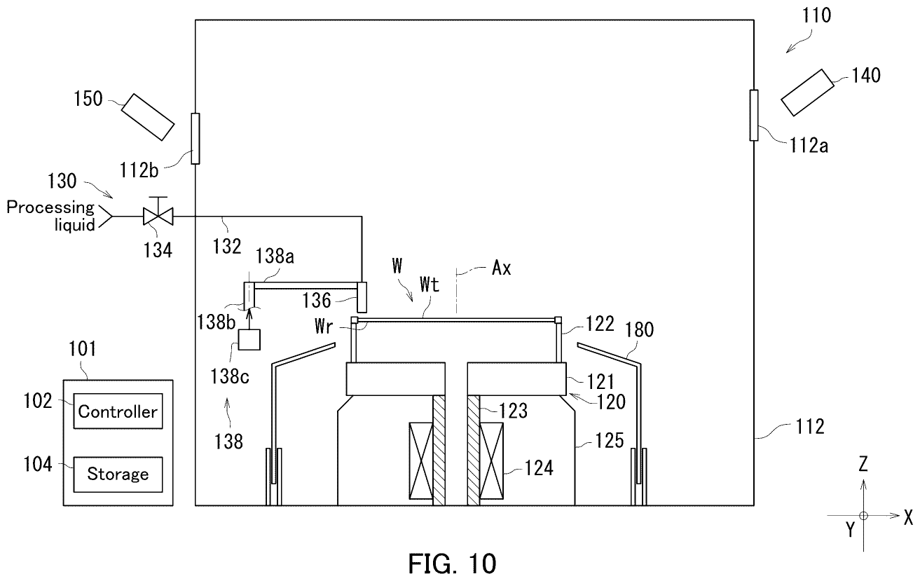

A substrate processing unit 110 in a substrate processing apparatus 100 according to the present embodiment is described next with reference to FIGS. 1 to 10. FIG. 10 is a schematic diagram of the substrate processing unit 110 in the substrate processing apparatus 100 according to the present embodiment. The substrate processing unit 110 in FIG. 10 has the same configuration as the substrate processing unit 110 in FIG. 2 except that a near-infrared light source 140 and a near-infrared imaging section 150 are placed outside windows 112a and 112b of the chamber 112. Duplicate descriptions are therefore omitted for the purpose of avoiding redundancy.

As depicted in FIG. 10, the near-infrared light source 140 and the near-infrared imaging section 150 are placed outside a chamber 112. For example, the near-infrared light source 140 and the near-infrared imaging section 150 are placed opposite to each other across the chamber 112. As a result of the near-infrared light source 140 and the near-infrared imaging section 150 being placed outside the chamber 112, a processing liquid is inhibited from attaching to the near-infrared light source 140 and the near-infrared imaging section 150.

Note that the chamber 112 preferably includes windows 112a and 112b. For example, the windows 112a and 112b transmit at least near-infrared light. The windows 112a and 112b are preferably arranged on the respective opposite side surfaces of the chamber 112. For example, the near-infrared light source 140 emits near-infrared light toward a substrate W through the window 112a. The near-infrared imaging section 150 captures images of the substrate W through the window 112b.

In a plan view of the substrate processing unit 110, the optical axis of the near-infrared light source 140 and the imaging optical axis of the near-infrared imaging section 150 are located on a straight line passing through the center of the substrate W. As such, the near-infrared light source 140 and the near-infrared imaging section 150 may be placed at positions projected on a horizontal line passing through the center of the substrate W.

Alternatively, in a plan view of the substrate processing unit 110, the optical axis of the near-infrared light source 140 and the imaging optical axis of the near-infrared imaging section 150 may be perpendicular to each other at the center of the substrate W. As such, the near-infrared light source 140 and the near-infrared imaging section 150 may be placed at positions perpendicular to each other with respect to the center of the substrate W.

Although the processing liquid supply section 130 supplies one type of processing liquid to a substrate W in the substrate processing apparatuses 100 illustrated in FIGS. 2 and 10, the present embodiment is not limited to this. The processing liquid supply section 130 may supply multiple types of processing liquids to a substrate W.

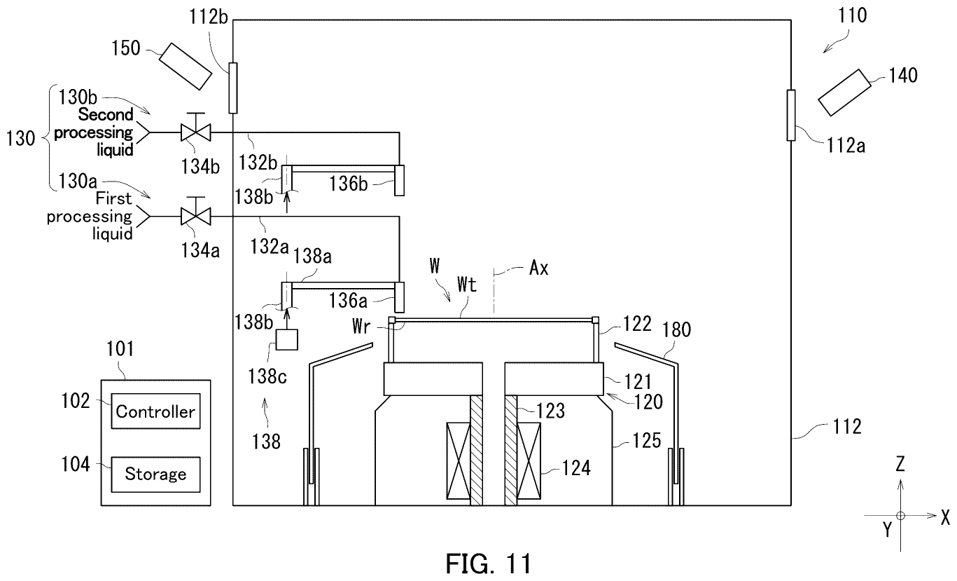

A substrate processing unit 110 in a substrate processing apparatus 100 according to the present embodiment is described next with reference to FIGS. 1 to 11. FIG. 11 is a schematic diagram of the substrate processing unit 110 in the substrate processing apparatus 100 according to the present embodiment. The substrate processing unit 110 in FIG. 11 has the same configuration as the substrate processing unit 110 described with reference to FIG. 2 except that a processing liquid supply section 130 includes a first processing liquid supply section 130a that supplies a first processing liquid and a second processing liquid supply section 130b that supplies a second processing liquid. Duplicate descriptions are therefore omitted for the purpose of avoiding redundancy.

As depicted in FIG. 11, the processing liquid supply section 130 includes a first processing liquid supply section 130 and a second processing liquid supply section 130b. The first processing liquid supply section 130a supplies a first processing liquid to a substrate W. The second processing liquid supply section 130b supplies a second processing liquid differing from the first processing liquid to the substrate W.

The first processing liquid supply section 130a includes a pipe 132a, a valve 134a, and a nozzle 136a. The first processing liquid is supplied to the pipe 132a from a supply source. The valve 134a opens and closes the flow path in the pipe 132a. The nozzle 136a is connected to the pipe 132a. The nozzle 136a discharges the first processing liquid to an upper surface Wt of the substrate W.

The second processing liquid supply section 130b includes a pipe 132b, a valve 134b, and a nozzle 136b. The second processing liquid is supplied to the pipe 132b from a supply source. The valve 134b opens and closes the flow path in the pipe 132b. The nozzle 136b is connected to the pipe 132b. The nozzle 136b discharges the second processing liquid onto the upper surface Wt of the substrate W.

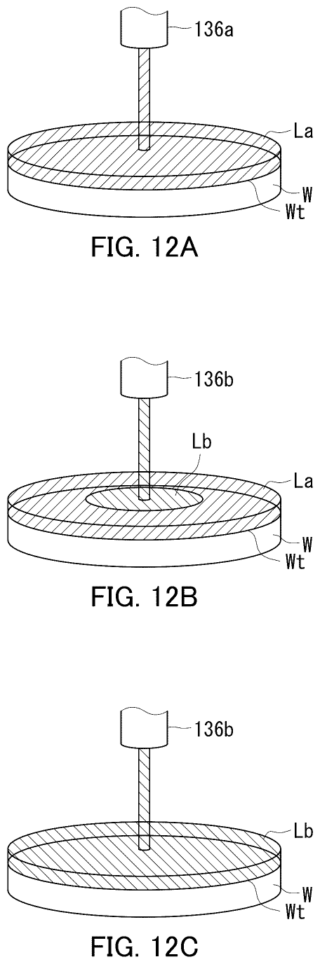

A substrate processing method according to the present embodiment is described next with reference to FIGS. 1 to 12C. FIG. 12A is a schematic diagram of a captured image obtained by capturing an image of a substrate W supplied with a first processing liquid La in a substrate processing apparatus 100 of the present embodiment. FIG. 12B is a schematic diagram of a captured image obtained by capturing an image of the substrate W in a state in which supply of a second processing liquid Lb has started after a supply stop of the first processing liquid La in the substrate processing apparatus 100 of the present embodiment. FIG. 12C is a schematic diagram of a captured image obtained by capturing an image of the substrate W supplied with the second processing liquid Lb in the substrate processing apparatus 100 of the present embodiment.

As depicted in FIG. 12A, a nozzle 136a discharges the first processing liquid La onto an upper surface Wt of the substrate W. Here, the nozzle 136a discharges the first processing liquid La toward the center of the upper surface Wt of the substrate W. Since the substrate W is rotated, the first processing liquid La spreads radially from the center of the upper surface Wt of the substrate W to cover the entirety of the upper surface Wt of the substrate W. Note that the first processing liquid La that has reached the radial edge of the upper surface Wt of the substrate W scatters radially outward from the substrate W. At this time point, the outer edge of the first processing liquid La covering the entirety of the upper surface Wt of the substrate W can be specified from the captured image.

As depicted in FIG. 12, the nozzle 136a stops discharging the first processing liquid La onto the upper surface Wt of the substrate W and then a nozzle 136b starts discharging the second processing liquid Lb onto the upper surface Wt of the substrate W. When the second processing liquid Lb is discharged subsequent to discharge of the first processing liquid La, the boundary between the first processing liquid La and the second processing liquid Lb spreads radially from the center of the upper surface Wt of the substrate W. At this time point, the outer edge of the first processing liquid La and the outer edge of the second processing liquid Lb can be specified from a captured image.

As also depicted in FIG. 12C, the nozzle 136b discharges the second processing liquid Lb onto the upper surface Wt of the substrate W. Here, the nozzle 136b discharges the second processing liquid Lb toward the center of the upper surface Wt of the substrate W. Since the substrate W is rotated, the second processing liquid Lb spreads radially from the center of the upper surface Wt of the substrate W to cover the entirety of the upper surface Wt of the substrate W. Note that the second processing liquid Lb that has reached the radial edge of the upper surface Wt of the substrate W scatters radially outward from the substrate W. At this time point, the outer edge of the second processing liquid Lb covering the entirety of the upper surface Wt of the substrate W can be specified from a captured image.

According to the present embodiment, an image of the first processing liquid La and the second processing liquid Lb illuminated with near-infrared light is captured using the near-infrared imaging section 150. The first processing liquid La and the second La processing liquid Lb absorb near-infrared light at a relatively high rate, so that the outer edges of the first processing liquid La and the second processing liquid Lb can be specified with high precision. In addition, the first processing liquid La and the second La processing liquid Lb absorb near-infrared light in different manners, so that the types of the first processing liquid La and the second processing liquid Lb can be specified with high precision.

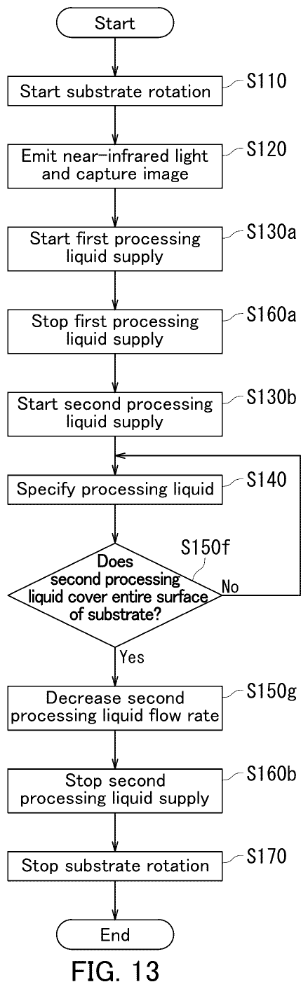

A substrate processing method according to the present embodiment is described next with reference to FIGS. 1 to 13. FIG. 13 is a flow chart depicting the substrate processing method. The flow chart of FIG. 13 is the same as the flow chart described with reference to FIG. 5 except that a first processing liquid and a second processing liquid are respectively supplied from a first processing liquid supply section 130a and a second processing liquid supply section 130b. Duplicate descriptions are therefore omitted for the purpose of avoiding redundancy.

As depicted in FIG. 13, Steps S110 and S120 are the same as those in FIG. 5. Description is therefore omitted. After Step S120, the routine proceeds to Step S130a.

In Step S130a, a first processing liquid La is supplied onto an upper surface Wt of a substrate W. In detail, a first processing liquid supply section 130a starts supplying the first processing liquid La onto the upper surface Wt of the substrate W. Specifically, a controller 102 controls the first processing liquid supply section 130a so that supply of the first processing liquid La onto the upper surface Wt of the substrate W starts. The routine proceeds to Step S160a.

In step S160a, supply of the first processing liquid is stopped. In detail, the first processing liquid supply section 130a stops supplying the first processing liquid onto the upper surface Wt of the substrate W. Specifically, the controller 102 controls the first processing liquid supply section 130a so that supply of the first processing liquid La is stopped after a predetermined period elapses from the start supply of processing liquid. The routine proceeds to Step S130b.

In Step S130b, a second processing liquid Lb is supplied onto the upper surface Wt of the substrate W. In detail, a second processing liquid supply section 130b starts supplying the second processing liquid Lb onto the upper surface Wt of the substrate W. Here, the second processing liquid supply starts when supply of the first processing liquid La to the substrate W stops. The routine proceeds to Step S140.

In Step S140, the second processing liquid Lb in a captured image generated by a near-infrared imaging section 150 is specified based on the captured image. The controller 102 specifies the outer edge of the second processing liquid Lb in the captured image based on the captured image. The controller 102 may also specify the type of the second processing liquid Lb in the captured image based on the captured image. The routine proceeds to Step S150f.

In step S150f, whether or not the second processing liquid Lb has covered the entirety of the upper surface Wt of the substrate W is determined. Specifically, the controller 102 determines whether or not the second processing liquid Lb has covered the entirety of the upper surface Wt of the substrate W based on the results of specifying the outer edge of the second processing liquid Lb.

If the second processing liquid Lb has not covered the entirety of the upper surface Wt of the substrate W (No in Step S150f), the routine returns to Step S140. In the manner described above, specification of the outer edge of the second processing liquid Lb and determination as to entire surface covering with the second processing liquid Lb are repeated until the second processing liquid Lb covers the entirety of the upper surface Wt of the substrate W. If the second processing liquid Lb has covered the entirety of the upper surface Wt of the substrate W (Yes in Step S150f) by contrast, the routine proceeds to Step S150g.

In Step S150g, the flow rate of the second processing liquid Lb to be supplied to the substrate W is decreased. The controller 102 controls the second processing liquid supply section 130b so that the flow rate of the second processing liquid Lb to be supplied to the substrate W by the second processing liquid supply section 130b is decreased. Thereafter, the routine proceeds to Step S160b.

In step S160b, supply of the second processing liquid Lb is stopped. In detail, the second processing liquid supply section 130b stops supplying the second processing liquid Lb onto the upper surface Wt of the substrate W. Specifically, the controller 102 controls the second processing liquid supply section 130b so that supply of the second processing liquid Lb is stopped after a predetermined period elapses from replacement of the entirety of the upper surface Wt of the substrate W by the second processing liquid Lb. The routine proceeds to Step S170. Note that Step S170 is the same as Step S170 in FIG. 5.

In the present embodiment, the near-infrared imaging section 150 captures images of the first processing liquid La and the second processing liquid Lb illuminated with near-infrared light. The first processing liquid La and the second processing liquid Lb absorb near-infrared light at a relatively high rate, so that the outer edges of the first processing liquid La and the second processing liquid Lb can be specified with high precision. In addition, the first processing liquid La and the second processing liquid Lb absorb near-infrared light in different manners, so that the types of the first processing liquid La and the second processing liquid Lb can be specified with high precision.

Although the near-infrared imaging section 150 captures an image of a substrate W supplied with a processing liquid and near-infrared light illumination and image capture are performed in a period during which the processing liquid is supplied to the substrate W in the above description with reference to FIGS. 5 to 13, the present embodiment is not limited to this. The near-infrared imaging section 150 may capture images in any region in a chamber 112, and near-infrared light illumination and image capture may be performed after a processing liquid is supplied to a substrate W.

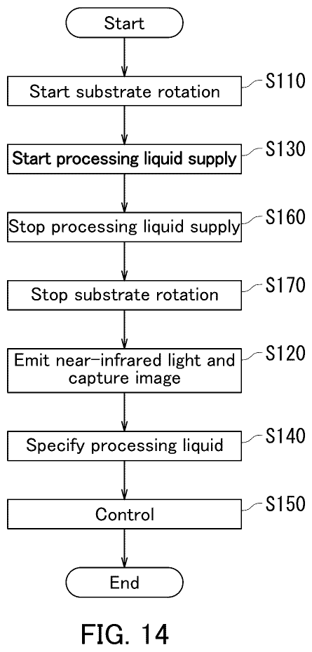

A substrate processing process in a substrate processing method according to the present embodiment is described next with reference to FIGS. 1 to 14. FIG. 14 is a flow chart of the substrate processing process in the substrate processing method according to the present embodiment. The flow chart of FIG. 14 is the same as the flow chart described with reference to FIG. 5 except that suck back is performed after a supply stop of a processing liquid in Step S160 and that Step S120 (near-infrared light illumination/image capture) and Step S150 (control) are performed after Step S120. Duplicate descriptions are therefore omitted for the purpose of avoiding redundancy.

In step S110, a substrate W is rotated with the substrate W held. Specifically, a substrate holding section 120 rotates the substrate W while holding the substrate W. For example, the rotational speed of the substrate W at this time point is between 10 rpm and 1500 rpm.

In Step S130, a processing liquid is supplied to the substrate W. Specifically, a controller 102 controls a processing liquid supply section 130 to cause the processing liquid supply section 130 to start supplying the processing liquid to the substrate W.

In step S160, the processing liquid supply is stopped. Specifically, the controller 102 stops the processing liquid supply to the substrate W by the processing liquid supply section 130. Here, the processing liquid is sucked back to a pipe 132 after a supply stop of the processing liquid. The routine proceeds to Step S170.

In Step S170, the rotation of the substrate W is stopped. Specifically, the controller 102 stops the substrate holding section 120 from rotating the substrate W. The routine proceeds to Step S120.

In Step S120, a near-infrared light source 140 illuminates the pipe 132 and a nozzle 136 with near-infrared light and a near-infrared imaging section 150 generates a captured image by capturing an image of the pipe 132 and the nozzle 136 illuminated with the near-infrared light. The controller 102 controls the near-infrared light source 140 and the near-infrared imaging section 150 so that the near-infrared light source 140 emits near-infrared light toward the pipe 132 and the nozzle 136 and the near-infrared imaging section 150 captures an image of the pipe 132 and the nozzle 136 illuminated with the near-infrared light. Note that the near-infrared imaging section 150 may capture an image of at least one of the pipe 132 and the nozzle 136 and the near-infrared light source 140 may illuminate at least one of the pipe 132 and the nozzle 136 of which image is to be captured by the near-infrared imaging section 150.

In step S140, the processing liquid in the captured image generated by the near-infrared imaging section 150 is specified based on the captured image. The controller 102 specifies the processing liquid in the captured image based on the captured image. For example, the controller 102 specifies the outer edge of the processing liquid in the captured image based on the captured image. In the manner described above, the position of the processing liquid sucked back in the pipe 132 and the nozzle 136 can be specified. The controller 102 may also specify the type of the processing liquid in the captured image based on the captured image. The routine proceeds to Step S150.

In Step S150, the controller 102 controls the processing liquid in a chamber 112. The near-infrared imaging section 150 captures an image of the pipe 132 and the nozzle 136 illuminated with near-infrared light in Step S140. Therefore, an image of the processing liquid in the pipe 132 and the nozzle 136 can be captured with high precision. For example, if suck back of the processing liquid is insufficient in Step S160, the controller 102 causes re-execution of suck back of the processing liquid.

In the present embodiment, an image of the pipe 132 and the nozzle 136 illuminated with near-infrared light from the near-infrared light source 140 is captured by the near-infrared imaging section 150. Therefore, the processing liquid in the pipe 132 and the nozzle 136 can be specified with high precision. For example, detection of a processing liquid being insufficiently sucked back in a captured image obtained by the near-infrared imaging section 150 can cause re-execution of suck back of the processing liquid.

Embodiments of the present invention have been described so far with reference to the drawings. However, the present invention is not limited to the above embodiments and can be reduced into practice in various manners within a scope not departing from the essence thereof. Also, various inventions can be formed by appropriate combination of elements of configuration disclosed in the above embodiments. For example, some of all the elements of configuration indicated in the embodiments may be omitted. Alternatively or additionally, elements of configuration in different embodiments may be combined as appropriate. The drawings schematically illustrate elements of configuration in order to facilitate understanding. Properties such as the thickness, length, number, and intervals of each element of configuration illustrated in the drawings may differ from actual properties in order to facilitate preparation of the drawings. Furthermore, material, shape, dimension, and the like of each element of configuration indicated in the above embodiments are examples and not particular limitations. Various alterations may be made so long as there is no substantial deviation from the effects of the present invention.

### INDUSTRIAL APPLICABILITY

The present invention is suitably used in substrate processing apparatuses and substrate processing methods.

### REFERENCE SIGNS LIST

100 Substrate processing apparatus
110 Substrate processing unit
112 Chamber
120 Substrate holding section
130 Processing liquid supply section
140 Near-infrared light source
150 Near-infrared imaging section
W Substrate

1. A substrate processing apparatus, comprising:
a chamber;
a substrate holding section that rotates a substrate while holding the substrate in the chamber;
a processing liquid supply section that supplies a processing liquid onto an upper surface of the substrate;
a near-infrared light source that illuminates an inside of the chamber with near-infrared light;
a near-infrared imaging section that generates a captured image by capturing an image of the processing liquid in the chamber illuminated with the near-infrared light from the near-infrared light source; and
a controller that specifies an outer edge of the processing liquid in the chamber based on the captured image.

2. The substrate processing apparatus according to claim 1, wherein
the controller specifies a type of the processing liquid based on the captured image.

3. The substrate processing apparatus according to claim 1, wherein
the near-infrared imaging section captures the image of the processing liquid in a state in which the upper surface of the substrate is supplied with the processing liquid.

4. The substrate processing apparatus according to claim 3, wherein
the controller determines whether or not the processing liquid has covered an entirety of the upper surface of the substrate based on the captured image.

5. The substrate processing apparatus according to claim 1, wherein:
the processing liquid supply section includes:
a first processing liquid supply section that supplies a first processing liquid to the substrate; and
a second processing liquid supply section that supplies a second processing liquid to the substrate, and
the controller determines whether or not the second processing liquid has covered an entirety of the upper surface of the substrate based on the captured image after a supply start of the second processing liquid from the second processing liquid supply section to the substrate following a supply stop of the first processing liquid from the first processing liquid supply section to the substrate.

6. The substrate processing apparatus according to claim 1, wherein
the near-infrared light source and the near-infrared imaging section are placed outside the chamber.

7. The substrate processing apparatus according to claim 6, wherein
the near-infrared light source and the near-infrared imaging section are placed opposite to each other across the chamber.

8. The substrate processing apparatus according to claim 1, wherein
the near-infrared light source and the near-infrared imaging section are placed inside the chamber.

9. The substrate processing apparatus according to claim 1, wherein
the processing liquid supply section includes a pipe and a nozzle, and
the near-infrared imaging section captures the image of the processing liquid, the processing liquid being located at at least one of the pipe and the nozzle.

10. A substrate processing method, comprising:
rotating a substrate while holding the substrate in a chamber;
supplying a processing liquid onto an upper surface of the substrate in the chamber;
illuminating an inside of the chamber with near-infrared light;
generating a captured image by capturing an image of the processing liquid in the chamber illuminated with the near-infrared light; and
specifying an outer edge of the processing liquid in the chamber based on the captured image.

11. The substrate processing method according to claim 10, further comprising
specifying a type of the processing liquid based on the captured image.

12. The substrate processing method according to claim 10, wherein
in the generating, the image of the processing liquid is captured in a state in which the upper surface of the substrate is supplied with the processing liquid.

13. The substrate processing method according to claim 12, further comprising
determining whether or not the processing liquid has covered an entirety of the upper surface of the substrate.

14. The substrate processing method according to claim 10, wherein
the supplying includes:
supplying a first processing liquid to the substrate; and
supplying a second processing liquid to the substrate, and
the substrate processing method further comprises
determining whether or not the second processing liquid has covered an entirety of the upper surface of the substrate based on the captured image after a supply start of the second processing liquid to the substrate following a supply stop of the first processing liquid to the substrate.

15. The substrate processing method according to claim 10, wherein
in the generating, the image of the processing liquid is captured, the processing liquid being located at at least one of a pipe and a nozzle that allow the processing liquid to flow through.
